(19) United States
(12) Patent Application Publication
(10) Pub. No.: US 2026/0013378 A1
(43) Pub. Date: Jan. 8, 2026

(54) DISPLAY MODULE, MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shengxing ZHANG, Beijing (CN); Jiafan SHI, Beijing (CN); Chao YANG, Beijing (CN); Pan HU, Beijing (CN); Yang YANG, Beijing (CN); Mengyuan PANG, Beijing (CN); Chuandong LIAO, Beijing (CN)

(21) Appl. No.: 18/881,799

(22) PCT Filed: May 29, 2024
(86) PCT No.: PCT/CN2024/096128

§ 371 Date: Jan. 7, 2025

(30) Foreign Application Priority Data
May 29, 2023 (CN) 202310622325.2

(51) Int. Cl. H10K 59/80; H10K 59/12; H10K 59/122; H10K 102/00

(52) U.S. Cl. CPC H10K 59/878; H10K 59/1201; H10K 59/122; H10K 59/873; H10K 59/8792; H10K 2102/3023; H10K 2102/311; H10K 2102/351

(57) ABSTRACT

Provided is a display module. The display module includes: a display panel, a transparent adhesive layer, a cover plate, a light-shielding layer, and a first reflective layer. The transparent adhesive layer is disposed on a side of a light-exiting surface of the display panel. The light-shielding layer is disposed between the cover plate and the display panel, and an orthographic projection of the light-shielding layer on the display panel is within the peripheral region of the display panel. The first reflective layer is disposed between the transparent adhesive layer and the light-shielding layer, and an orthographic projection of the first reflective layer on the display panel is within the peripheral region of the display panel and is overlapped with the orthographic projection of the light-shielding layer on the display panel.

### CROSS-REFERENCE TO RELATED APPLICATIONS

This application is a U.S. national stage of international application No. PCT/CN2024/096128, filed on May 29, 2024, which claims priority to Chinese Patent Application No. 202310622325.2, filed on May 29, 2023, entitled “DISPLAY MODULE, MANUFACTURING METHOD OF DISPLAY MODULE AND DISPLAY DEVICE,” the disclosures of which are herein incorporated by reference in their entireties.

### TECHNICAL FIELD

The present disclosure relates to the field of display technologies, and in particular, relates to a display module, a manufacturing method therefor, and a display device.

### BACKGROUND

An organic light-emitting diode (OLED) is also known as an organic electroluminescence display (OLED) or an organic light-emitting semiconductor. The OLED emits light through injection and recombination of carriers in the case that an organic semiconductor material and a light-emitting material are driven by an electric field. Compared with a traditional liquid crystal panel or screen including a thin film transistor (TFT), the OLED has characteristics of faster response, higher contrast, wider viewing angle, smaller weight and thickness, better flexibility, and the like.

### SUMMARY

The present disclosure provides a display module, a manufacturing method therefor, and a display device.

According to an aspect, a display module is provided. The display module includes: a display panel, wherein the display panel includes a display region and a peripheral region surrounding the display region;
a transparent adhesive layer, wherein the transparent adhesive layer is disposed on a side of a light-exiting surface of the display panel;
a cover plate, wherein the cover plate is disposed on a side, away from the display panel, of the transparent adhesive layer;
a light-shielding layer, wherein the light-shielding layer is disposed between the cover plate and the display panel, and an orthographic projection of the light-shielding layer on the display panel is within the peripheral region of the display panel; and
at least one reflective layer, wherein the at least one reflective layer includes a first reflective layer disposed between the transparent adhesive layer and the light-shielding layer, an orthographic projection of the first reflective layer on the display panel being within the peripheral region of the display panel and being overlapped with the orthographic projection of the light-shielding layer on the display panel.

In some embodiments, the orthographic projection of the first reflective layer on the display panel is completely overlapped with the orthographic projection of the light-shielding layer on the display panel.

In some embodiments, the at least one reflective layer further includes a second reflective layer disposed between the transparent adhesive layer and the display panel, an orthographic projection of the second reflective layer on the display panel being within the peripheral region of the display panel and being overlapped with the orthographic projection of the light-shielding layer (130) on the display panel.

In some embodiments, the orthographic projection of the second reflective layer on the display panel is completely overlapped with the orthographic projection of the light-shielding layer on the display panel.

In some embodiments, any of the at least one reflective layer includes a plurality of layers of composite structure, each of the plurality of layers of composite structure including niobium oxide and silicon dioxide arranged in a stacked configuration.

In some embodiments, any of the at least one reflective layer includes five layers of composite structure, each of the five layers of composite structure having a thickness ranging from 100 nm to 800 nm.

In some embodiments, the light-shielding layer includes a first flat portion and a second flat portion sequentially stacked in a direction close to the light-exiting surface of the display panel, an area of an orthographic projection of the first flat portion on the display panel being greater than an area of an orthographic projection of the second flat portion on the display panel.

In some embodiments, the orthographic projection of the second flat portion on the display panel is within a center region of the orthographic projection of the first flat portion on the display panel.

In some embodiments, a cross-section of the light-shielding layer in a direction perpendicular to the light-exiting surface of the display panel is at least one of: a planar shape, a wavy shape, or a groove structure, the groove structure having an opening facing the display panel.

In some embodiments, a material of the transparent adhesive layer includes an optically clear adhesive or an optical clear resin.

In some embodiments, the display panel includes a substrate and a plurality of light-emitting devices, a pixel definition layer, and a encapsulation layer sequentially disposed on a side of the substrate, the pixel definition layer being configured to separate the plurality of light-emitting devices.

In some embodiments, the light-emitting device is a bottom-emitting device, and the encapsulation layer includes a first inorganic layer, an organic layer, and a second inorganic layer that are stacked in a direction away from the substrate; and
the display module further includes a waterproof layer and a first adhesive layer, the waterproof layer being disposed on a side, away from the substrate, of the second inorganic layer, and the first adhesive layer being disposed between the second inorganic layer and the waterproof layer.

In some embodiments, the waterproof layer is made of aluminum foil or copper foil.

In some embodiments, in a direction parallel to a plane in which the substrate extends, an edge of the organic layer is inwardly retracted by 1 mm to 2 mm relative to edges of the first inorganic layer and the second inorganic layer; and
the display module further includes a first glue film, the first glue film being disposed in the same layer as the organic layer and configured to adhere the first inorganic layer to the second inorganic layer.

In some embodiments, in a direction parallel to a plane in which the substrate extends, outer edges of the waterproof layer and the second inorganic layer are flush and both inwardly retracted by 0.5 mm to 1 mm relative to an edge of the first inorganic layer; and an edge of the organic layer is inwardly retracted by 1 mm to 2 mm relative to the edge of the first inorganic layer; and
the display module further includes a second glue film, the second glue film covering a surface, away from the substrate, of the waterproof layer, and side surfaces of the waterproof layer, the first adhesive layer, the second inorganic layer, the organic layer, and the first inorganic layer.

According to another aspect, a method for manufacturing a display module is provided. The method is applicable to manufacturing the display module as described in any one of the above aspects, and the method includes:
forming a display panel, wherein the display panel includes a display region and a peripheral region surrounding the display region;
forming a transparent adhesive layer on a side of a light-exiting surface of the display panel;
forming a light-shielding layer on a side, away from the display panel, of the transparent adhesive layer, wherein an orthographic projection of the light-shielding layer on the display panel is within the peripheral region of the display panel;
forming a first reflective layer on a side, close to the display panel, of the light-shielding layer, wherein an orthographic projection of the first reflective layer on the display panel is within the peripheral region of the display panel and is overlapped with an orthographic projection of the light-shielding layer on the display panel; and
forming a cover plate on a side, away from the display panel, of the light-shielding layer.

In some embodiments, forming the first reflective layer on the side, close to the display panel, of the light-shielding layer includes:
forming the first reflective layer on the side, close to the display panel, of the light-shielding layer through a non-conductive vacuum metalization process, a coating process, a bonding or hot-melt process.

In some embodiments, prior to forming the transparent adhesive layer on the side of the light-exiting surface of the display panel, the method further includes:
forming a second reflective layer on the side of the light-exiting surface of the display panel, wherein an orthographic projection of the second reflective layer on the display panel is within the peripheral region of the display panel and is overlapped with the orthographic projection of the light-shielding layer on the display panel.

In some embodiments, forming the second reflective layer on the side of the light-exiting surface of the display panel includes:
forming the second reflective layer on the side of the light-exiting surface of the display panel through a non-conductive vacuum metalization process, a coating process, a bonding or hot-melt process.

According to yet another aspect, a display device is provided. The display device includes the display module as described in any one of the above aspects.

### BRIEF DESCRIPTION OF DRAWINGS

FIG. 1 is a schematic structural diagram of a display module according to some embodiments of the present disclosure;

FIG. 2 is a schematic diagram of a curing light source irradiating a transparent adhesive layer from a display region according to some embodiments of the present disclosure;

FIG. 3 is a schematic diagram of a curing light source irradiating a transparent adhesive layer from a side of a display module according to some embodiments of the present disclosure;

FIG. 4 is a schematic structural diagram of another display module according to some embodiments of the present disclosure;

FIG. 5 is a schematic diagram of a combined structure of a light-shielding layer and a reflective layer according to some embodiments of the present disclosure;

FIG. 6 is a schematic structural diagram of yet another display module according to some embodiments of the present disclosure;

FIG. 7 is a schematic structural diagram of yet another display module according to some embodiments of the present disclosure;

FIG. 8 is a schematic diagram of film layers of a display module according to some embodiments of the present disclosure;

FIG. 9 is a schematic structural diagram of still another display module according to some embodiments of the present disclosure;

FIG. 10 is a schematic structural diagram of a display module according to another embodiment of the present disclosure;

FIG. 11 is a schematic structural diagram of another display module according to another embodiment of the present disclosure;

FIG. 12 is a schematic structural diagram of yet another display module according to another embodiment of the present disclosure;

FIG. 13 is a schematic structural diagram of yet another display module according to another embodiment of the present disclosure;

FIG. 14 is a schematic diagram of the formation of a first adhesive layer according to some embodiments of the present disclosure;

FIG. 15 is a schematic diagram of the formation of a second inorganic layer according to some embodiments of the present disclosure;

FIG. 16 is a cross-sectional view of an edge of the display module illustrated in FIG. 7 according to some embodiments of the present disclosure; and

FIG. 17 is a flowchart of a method for manufacturing a display module according to some embodiments of the present disclosure.

### DETAILED DESCRIPTION

The technical solutions in the embodiments of the present disclosure is described clearly and completely hereinafter with reference to the accompanying drawings in the embodiments of the present disclosure. Apparently, the described embodiments are only some embodiments of the present disclosure, rather than all of the embodiments. Based on the embodiments in the present disclosure, all other embodiments acquired by a person of ordinary skill in the art based on the present disclosure fall within the protection scope of the present disclosure.

The OLED has been widely applied in electronic products such as cell phones, tablet computers, watches, or the like. With the development of display technologies, OLED flexible screens may be manufactured into various forms of display modules such as curved, foldable, special-shaped, or curled display modules due to their flexibility. Flexible products are being more and more widely used, and thus the improvement for the bending and curling performance is also becoming more and more important. Currently, for manufacturing an OLED flexible screen, an adhesive layer is needed to adhere, by absorbing the curing light to achieve post-curing, the display panel to the cover plate. In the post-curing process, because ink is disposed at an edge of a lower layer of the cover plate of the OLED flexible screen, in the case that the display panel is deformed or the angle of the curing light changes, the curing light is absorbed by the ink, resulting in that the curing light cannot penetrate the adhesive layer along the side of the adhesive layer. Therefore, the curing depth is limited, the curing effect is unsatisfactory, an adhesive force of the adhesive layer is not sufficient, and thus the edges of the OLED flexible screen are prone to cracking. In addition, a lower edge region of the OLED flexible screen is close to a bending region, and higher curing energy at the side is likely to damage the display panel. Therefore, it is not possible to use a curing light with higher energy, such that complete curing for the lower edge region of the OLED flexible screen is hard to achieve, which reduces the reliability and trustworthiness of the folding performance of the OLED flexible screen and lowers the performance and competitiveness of the display product.

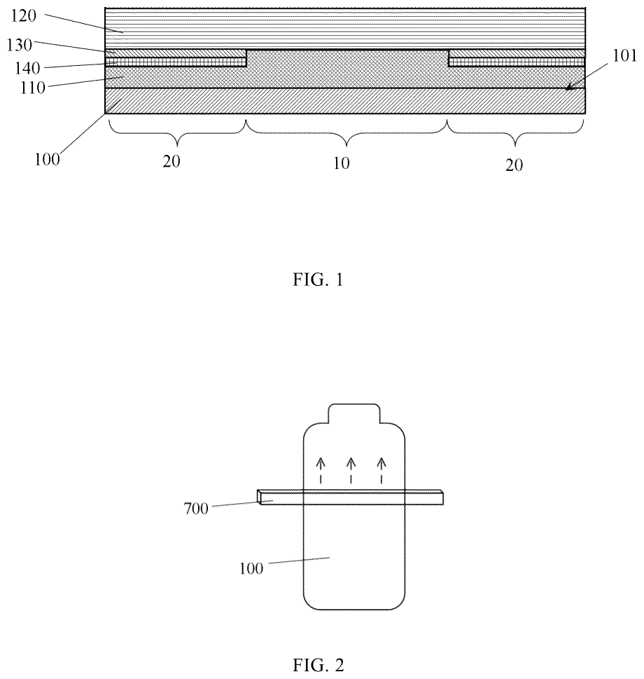

To improve the folding trustworthiness of the OLED flexible screen and improve the performance and competitiveness of the product, embodiments of the present disclosure provide a display module. Illustratively, FIG. 1 is a schematic structural diagram of a display module according to some embodiments of the present disclosure. As shown in FIG. 1, the display module includes a display panel 100, a transparent adhesive layer 110, a cover plate 120, a light-shielding layer 130, and at least one reflective layer. The at least one reflective layer includes a first reflective layer 140.

The display panel 100 includes a display region 10 and a peripheral region 20 surrounding the display region 10.

The transparent adhesive layer 110 is disposed on a side of a light-exiting surface 101 of the display panel 100. The cover plate 120 is disposed on a side, away from the display panel 100, of the transparent adhesive layer 110.

The light-shielding layer 130 is disposed between the cover plate 120 and the display panel 100, and an orthographic projection of the light-shielding layer 130 on the display panel 100 is within the peripheral region of the display panel 100. In the embodiments of the present disclosure, by disposing the light-shielding layer 130 between the cover plate 120 and the display panel 100 and in the peripheral region 20 of the display panel 100, the metal traces in the peripheral region 20 of the display panel 100 are shielded by the light-shielding layer 130, thereby ensuring that the appearance requirements for the display module are satisfied.

The first reflective layer 140 is disposed between the transparent adhesive layer 110 and the light-shielding layer 130, i.e., the first reflective layer 140 is disposed on a side, away from the display panel 100, of the transparent adhesive layer 110 and on a side, close to the display panel 100, of the light-shielding layer 130. An orthographic projection of the first reflective layer 140 on the display panel 100 is overlapped with the orthographic projection of the light-shielding layer 130 on the display panel 100. In some embodiment, a side, away from the light-exiting surface 101 of the display panel 100, of the first reflective layer 140 is attached to the light-shielding layer 130, and a side, close to the light-exiting surface 101 of the display panel 100, of the first reflective layer 140 is attached to the transparent adhesive layer 110.

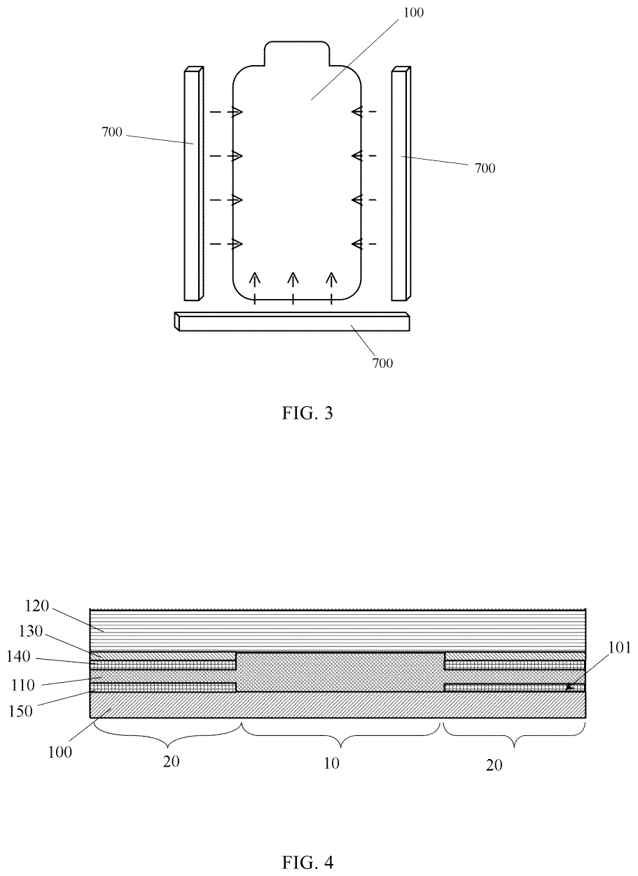

The transparent adhesive layer 110 is configured to adhere the display panel 100 to the cover plate 120. In the adhering process, in the case that the transparent adhesive layer 110 is printed or coated on the display panel 100, the transparent adhesive layer 110 is first pre-cured, i.e., a curing light source is used to irradiate the surface of the transparent adhesive layer 110, such that a surface of the transparent adhesive layer 110 is first cured. In the case that the cover plate 120 is attached to the transparent adhesive layer 110, the curing light source is then used to irradiate the transparent adhesive layer 110 to achieve the post-curing (i.e., the deep curing of the transparent adhesive layer 110), which in turn makes the display panel 100 be sufficiently adhered to the cover plate, so as to improve the folding performance of the flexible display screen. In the embodiments of the present disclosure, the curing light source is set to irradiate the transparent adhesive layer 110 respectively from the top of the display module (i.e., the display region 10) and from the side of the display module. Illustratively, FIG. 2 is a schematic diagram of the curing light source irradiating the transparent adhesive layer from the display region according to some embodiments of the present disclosure. As shown in FIG. 2, in some embodiments, the curing light source 700 irradiates the transparent adhesive layer 110 from the display region 10 of the display module, such that the intermediate portion of the transparent adhesive layer 110 that is not shielded by the light-shielding layer 130 is deeply cured, which in turn enables the cover plate 120 and the intermediate portion of the display panel 100 to be sufficiently adhered. Illustratively, FIG. 3 is a schematic diagram of the curing light source irradiating the transparent adhesive layer from the side of the display module according to some embodiments of the present disclosure. As shown in FIG. 3, in some embodiments, the curing light source 700 irradiates the transparent adhesive layer 110 from the side edge of the display module, which achieves the deep curing of the edge of the transparent adhesive layer 110, and thus enables the cover plate 120 and the edge portion of the display panel 100 to be fully adhered.

During the curing process for the transparent adhesive layer 110 by disposing the curing light source to irradiate the transparent adhesive layer from the display region, due to the provision of the light-shielding layer 130 between the cover plate 120 and the display panel 100, some curing light perpendicular to the transparent adhesive layer 110 is absorbed by the light-shielding layer 130, resulting in that the curing light cannot irradiate the transparent adhesive layer 110, which in turn results in that the edges of the transparent adhesive layer 110 are not cured or cured incompletely. During the curing process for the transparent adhesive layer 110 by disposing the curing light source to irradiate the transparent adhesive layer from the side of the display module, in the case that the position of the curing light source 700 is tilted or the display panel 100 is deformed, the curing light is not parallel to the extension direction of the transparent adhesive layer 110, and at this time, the curing light irradiated to the light-shielding layer 130 is absorbed, and cannot penetrate the transparent adhesive layer 110 at the peripheral region 20, resulting in the curing light being unable to cause the side edges of the transparent adhesive layer to be completely cured. In the embodiments of the present disclosure, a first reflective layer 140 is disposed between the light-shielding layer 130 and the transparent adhesive layer 110, the first reflective layer 140 having excellent reflective properties. Therefore, in the case that the curing light irradiates the transparent adhesive layer 110 along the side of the display module, even if the curing light is not parallel to the transparent adhesive layer 110, the curing light is reflected to the transparent adhesive layer 110 by the first reflective layer 140, rather than directly reaching the light-shielding layer 130 and then being absorbed by light-shielding layer 130. In this way, the efficient utilization of the curing light is achieved, and the transparent adhesive layer 110 is fully irradiated by the curing light, which in turn enables the edges of the transparent adhesive layer 110 to be fully cured, improves the folding trustworthiness of the display module, and improves the performance and competitiveness of the product.

In some embodiments, the orthographic projection of the first reflective layer 140 on the display panel 100 is completely overlapped with the orthographic projection of the light-shielding layer 130 on the display panel 100. That is, the first reflective layer 140 completely covers the light-shielding layer 130, which reduces the probability that the curing light is absorbed by the light-shielding layer 130 during the process of the curing light irradiating the display module from the side of the display module.

In some embodiments, a material of the first reflective layer 140 includes, but is not limited to, aluminum trioxide, titanium dioxide, niobium oxide, zinc oxide, zirconium dioxide, or titanium dioxide. In some embodiments, the material of the first reflective layer 140 is a metal or adhesive material with high UV reflectivity. The embodiments of the present disclosure do not limit the material of the first reflective layer.

In some embodiments, a material of the light-shielding layer 130 includes, but is not limited to, black ink. In some embodiments, the material of the light-shielding layer 130 includes other black coating or plating. In some embodiments, the light-shielding layer 130 is formed by an inkjet printing process.

In some embodiments, a material of the cover plate 120 includes, but is not limited to, polyethylene terephthalate (PET), colorless Polyimide (CPI), or colorless glass.

In some embodiments, the at least one reflective layer described above further includes a second reflective layer. Illustratively, FIG. 4 is a schematic structural diagram of another display module according to some embodiments of the present disclosure. As shown in FIG. 4, on the basis of the display module illustrated in FIG. 1, the display module further includes a second reflective layer 150. The second reflective layer 150 is disposed between the transparent adhesive layer 110 and the display panel 100. An orthographic projection of the second reflective layer 150 on the display panel 100 is within the peripheral region 20 of the display panel 100 and is overlapped with the orthographic projection of the light-shielding layer 130 on the display panel 100.

In some embodiments, the orthographic projection of the second reflective layer 150 on the display panel 100 is completely overlapped with the orthographic projection of the light-shielding layer 130 on the display panel 100.

In this embodiment of the present disclosure, in the case that the curing light irradiates the first reflective layer 140 and the second reflective layer 150, due to the reflective properties of the first reflective layer 140 and the second reflective layer 150, the post-curing is performed on both the upper and lower surfaces of the transparent adhesive layer 110 at the same time. As compared to performing the post-curing from the upper layer of the transparent adhesive layer 110 only, the embodiments further improve the post-curing effect for the transparent adhesive layer 110. Further, because the first reflective layer 140 and the second reflective layer 150 are provided on the upper and lower surfaces of the transparent adhesive layer 110, the light that passes through the transparent adhesive layer 110 is reflected to the surface of the transparent adhesive layer 110 again. Therefore, the utilization efficiency of the reflected light is improved, and the transparent adhesive layer 110 is completely cured through the curing light with lower energy.

In some embodiments, a side, away from the light-exiting surface 101 of the display panel 100, of the second reflective layer 150 is attached to the transparent adhesive layer 110, and a side, close to the light-exiting surface 101 of the display panel 100, of the second reflective layer 150 is attached to the display panel 100.

In some embodiments, the second reflective layer 150 and the first reflective layer 140 have the same material and thickness.

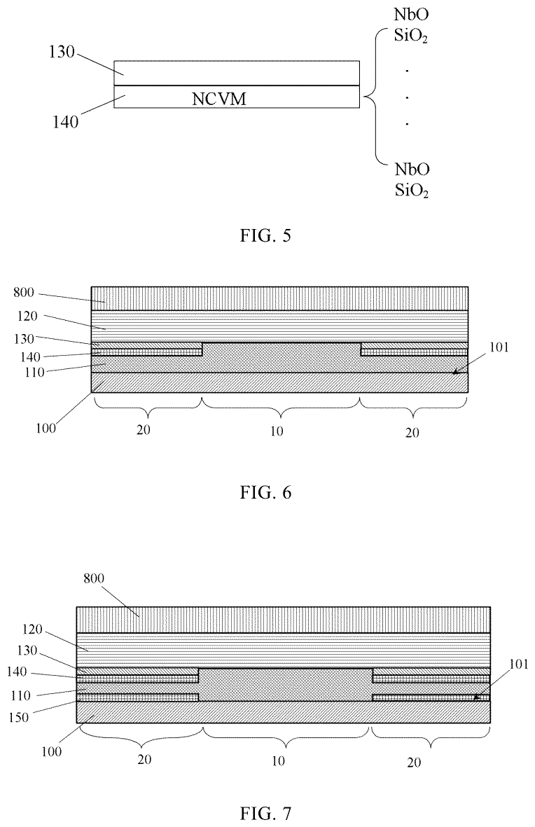

Illustratively, FIG. 5 is a schematic diagram of a combined structure of a light-shielding layer and a reflective layer according to some embodiments of the present disclosure. As shown in FIG. 5, the reflective layer (e.g., the first reflective layer 140 and the second reflective layer 150) includes a plurality of layers of composite structure, each of the plurality of layers of composite structure including niobium oxide and silicon dioxide arranged in a stacked configuration.

Referring to FIG. 5, in some embodiments, the reflective layer (e.g., first reflective layer 140) is a non-conductive vacuum metalization (NCVM) layer. The fact that the reflective layer includes a plurality of layers of composite structure allows the reflective layer to adequately reflect light. Because niobium oxide and silicon dioxide have different refractive indices, a higher reflectivity of the reflective layer is achieved by alternately stacking the mediums with the high and low refractive indices in the composite structure, which in turn leads to better curing of the edges of the transparent adhesive layer 110. In some embodiments, the composite structure is a stacked structure, and the order of layers in the stacked structure is not limited in the present disclosure. In some embodiments, along the direction of the light-shielding layer 130 toward the display panel 100, the stacking layers include niobium oxide, silicon dioxide, niobium oxide, and silicon dioxide, or silicon dioxide, niobium oxide, silicon dioxide, and niobium oxide.

In some embodiments, the reflective layer includes five layers of composite structure. In some embodiments, each of the first reflective layer 140 and the second reflective layer 150 includes five layers of composite structure. The thickness of each layer of the composite structure ranges from 100 nm to 800 nm, i.e., the thickness of the reflective layer ranges from 500 nm to 4000 nm. A thickness of 100 nm to 800 nm per layer allows the curing light to penetrate the stacked layers, thereby allowing the curing light to be adequately reflected between the first reflective layer 140 and the second reflective layer 150. In some embodiments, the thickness of each layer of the composite structure ranges from 200 nm to 400 nm.

Illustratively, FIGS. 6 and 7 are schematic structural diagrams of display modules according to some embodiments of the present disclosure. As shown in FIG. 6, on the basis of the display module illustrated in FIG. 1, a protective film 800 is disposed on a side, away from the display panel 100, of the cover plate 120. As shown in FIG. 7, on the basis of the display module illustrated in FIG. 4, a protective film 800 is disposed on a side, away from the display panel 100, of the cover plate 120. The protective film 800 is configured to prevent the cover plate 120 from being cut and rubbed, thereby increasing the service life of the display module.

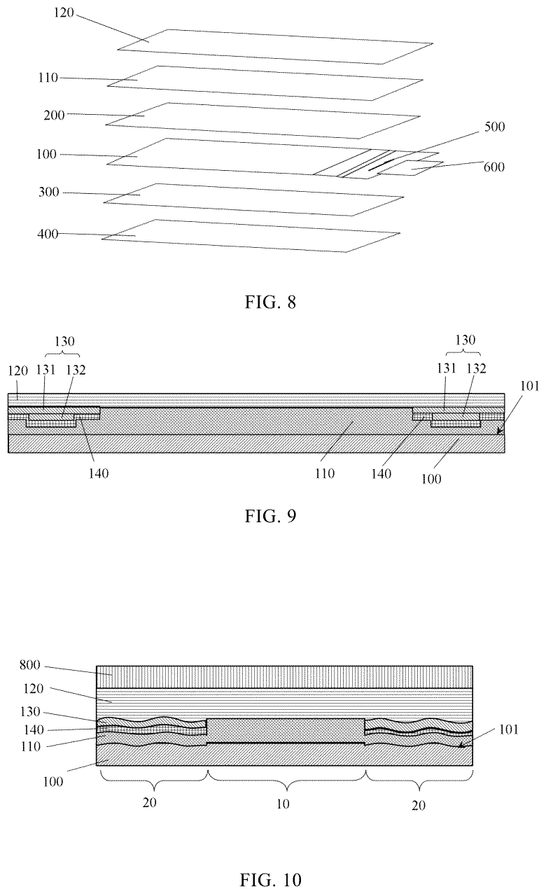

Illustratively, FIG. 8 is a schematic diagram of film layers of a display module according to some embodiments of the present disclosure. As shown in FIG. 8, the display module includes a display panel 100, a transparent adhesive layer 110, a cover plate 120, a polarizer 200, a back film 300, a support member 400, a control chip 500, and a flexible circuit board 600. In some embodiments, the back film 300 is made of a transparent insulating material, such as a polyester resin, and configured to protect and support the display panel 100.

Illustratively, FIG. 9 is a schematic structural diagram of yet another display module according to some embodiments of the present disclosure. As shown in FIG. 9, the light-shielding layer 130 includes a first flat portion 131 and a second flat portion 132 sequentially stacked along a direction close to the light-exiting surface 101 of the display panel 100. An area of an orthographic projection of the first flat portion 131 on the display panel 100 is greater than an area of an orthographic projection of the second flat portion 132 on the display panel 100.

In some embodiments of the present disclosure, as shown in FIG. 9, the area of the first flat portion 131 is greater than the area of the second flat portion 132, such that the light-shielding layer 130 has an inverted terraced structure. Thus, the transparent adhesive layer 110 fills the inverted terraced position, causing the thickness of the transparent adhesive layer 110 at the terraced position greater, and thus achieving a higher adhesive force between the cover plate 120 and the display panel 100 at the region covered by the light-shielding layer 130. Moreover, as shown in FIG. 9, the light-shielding layer 130 has an inverted terraced shape, such that the first reflective layer 140 also has an inverted terraced shape. Relative to a flat first reflective layer 140, the first reflective layer 140 with the inverted terraced shape makes the reflective area for the curing light increase, which in turn ensures that the curing light is more completely reflected to the transparent adhesive layer 110 and the curing effect of the transparent adhesive layer 110 is improved. Therefore, the folding trustworthiness of the display module is improved, and the performance and competitiveness of the product are improved.

In some embodiments, still referring to FIG. 9, the orthographic projection of the second flat portion 132 on the display panel 100 is within the center region of the orthographic projection of the first flat portion 131 on the display panel 100, i.e., the second flat portion 132 is disposed on the middle of the first flat portion 131.

In the embodiments of the present disclosure, in the case that the second flat portion 132 is disposed on the middle of the first flat portion 131, the two sides of the light-shielding layer 130 are symmetrical and both the two sides are inverted terraced, such that the curing light is possible to irradiate to the first reflective layer 140 from the two sides of the inverted terraced structure and be reflected, making more light be reflected to the transparent adhesive layer 110, and thus improving the curing effect of the transparent adhesive layer 110.

In some embodiments, a cross-section of the light-shielding layer 130 in a direction perpendicular to the light-exiting surface 101 of the display panel 100 is at least one of: a planar shape, a wavy shape, or a groove structure. That is, the cross-sectional shape is planar, wavy, or with a groove structure. The groove structure has an opening facing the display panel 100.

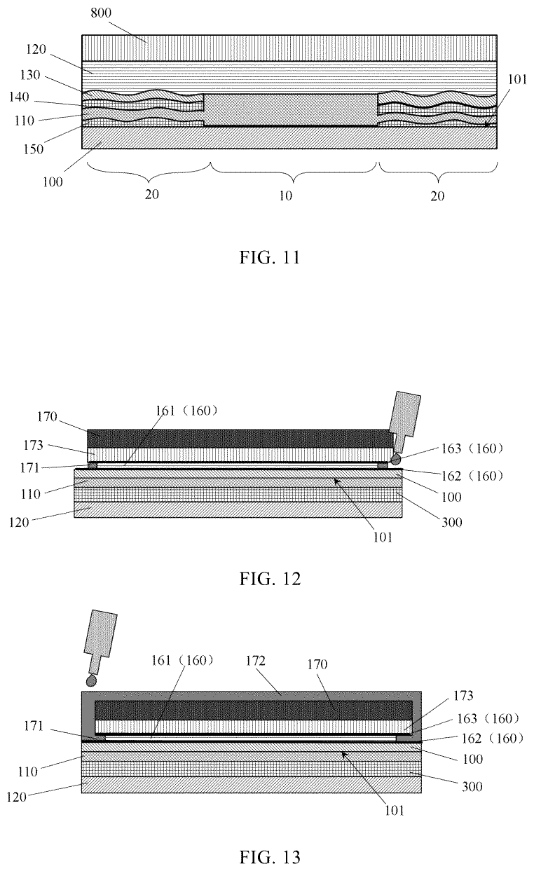

In some embodiments, referring to FIG. 1, FIG. 4, FIG. 6, or FIG. 7, the cross-section of the light-shielding layer 130 is planar, and the light-shielding layer 130 is attached to the cover plate 120. Compared to making the light-shielding layer 130 into other shapes, the light-shielding layer 130 with a flat cross-section is able to save a manufacturing process under the premise of completely shielding the metal traces. Illustratively, FIGS. 10 and 11 are schematic structural diagrams of display modules according to another embodiment of the present disclosure. As shown in FIG. 10 or FIG. 11, the cross-section of the light-shielding layer 130 is wavy. Because the cross-section of the light-shielding layer 130 is wavy, the transparent adhesive layer 110 and the first reflective layer 140 are also wavy, and the wavy structure does not affect the reflective property of the first reflective layer 140. In addition, in the case that the first reflective layer 140 and the second reflective layer 150 are wavy, the angle of reflection of the curing light changes. Because of the changed angles, the range in which the curing light is able to be reflected to and irradiate the transparent adhesive layer 110 is wider, which in turn improves the curing effect of the transparent adhesive layer 110. In some embodiments, in the case that the cross-section of the light-shielding layer 130 has a groove structure, the cross-section of the first reflective layer 140 has a raised structure that cooperates with the groove-type structure, and the height difference formed by the raised structure makes the reflective surface of the first reflective layer 140 larger, and thus makes the reflective effect for the curing light better.

In some embodiments, the material of the transparent adhesive layer 110 is an optically clear adhesive (OCA) or an optical clear resin (OCR).

The optically clear adhesive is a double-sided laminating tape without a base material. The optically clear adhesive has the advantages of high light transmittance, a high adhesive force, a uniform thickness, and a high degree of flatness, and has no problems such as yellowing, aging, fogging, detachment from the surface to be adhered to, or producing bubbles over a long period of time of working. By using the optically clear adhesive as the transparent adhesive layer 110 to adhere the cover plate 120 to the display panel 100, the display module has good adhesion and stability during use. Compared to the optically clear adhesive, the optical clear resin has a free shape, does not need to be cut, and can be adjusted by a program to correspond to various shapes such as dug holes, special shapes, 3D shapes, and so on. The optical clear resin has a wide selection range of thicknesses and excellent filling performance and thus meets the needs of different thicknesses at different positions on the same piece of product. Optical clear resins further have excellent folding properties. By using the optical clear resin as the transparent adhesive layer 110, a smaller folding radius, a longer folding life, a more severe folding reliability environment, and the like, of the display module are achieved.

Illustratively, FIG. 12 and FIG. 13 are schematic structural diagrams of display modules according to some embodiments of the present disclosure. As shown in FIG. 12 or FIG. 13, the display panel 100 includes a substrate and a plurality of light-emitting devices (not shown in the figures), a pixel definition layer (not shown in the figures), and a encapsulation layer 160 sequentially disposed on a side of the substrate. The pixel definition layer is configured to separate the plurality of light-emitting devices.

The light-emitting device is a top-emitting device or bottom-emitting device. The light-emitting devices are categorized into top-emitting devices and bottom-emitting devices according to the direction in which light is emitted from the device. Top-emitting devices are widely used in cell phones or the like, because the top-emitting device applies an optical microcavity structure and thus has a frontal brightness improved by multiple times relative to bottom-emitting devices. Top-emitting devices have ultra-thin metal electrodes, and thus the top-emitting devices have poor stability, are prone to corrosion by water vapor, and therefore have higher packaging requirements. As for the bottom-emitting device, because the bottom-emitting device has a thicker cathode, the bottom-emitting device has better stability. In addition, because the light-exiting side of the bottom-emitting device is generally at the non-metallic anode farther away from the light-emitting layer, the optical loss of the bottom-emitting device is smaller.

In some embodiments, the light-emitting device is a bottom-emitting device. As shown in FIG. 12 or FIG. 13, the encapsulation layer 160 includes a first inorganic layer 162, an organic layer 161, and a second inorganic layer 163 that are stacked in a direction away from the substrate. The display module further includes a waterproof layer 170 and a first adhesive layer 173. The waterproof layer 170 is disposed on a side, away from the substrate, of the second inorganic layer 163. The first adhesive layer 173 is disposed between the second inorganic layer 163 and the waterproof layer 170. In other words, the second inorganic layer 163 is provided with the waterproof layer 170 on the side away from the substrate. The waterproof layer 170 is adhered to the second inorganic layer 163 through the first adhesive layer 173.

In the embodiments of the present disclosure, the light-emitting side of the display module is the bottom side, with less optical loss. As shown in FIG. 12 or FIG. 13, the waterproof layer 170 is disposed on a side of the encapsulation layer 160, which gives the display module a certain waterproof performance, improves the packaging effect, and extends the service life of the display module. The organic layer 161 is disposed between the first inorganic layer 162 and the second inorganic layer 163 so as to achieve planarization and reduce the stress in the encapsulation layer 160.

In some embodiments, the materials of the first inorganic layer 162 and the second inorganic layer 163 are different. In some embodiments, the first inorganic layer 162 has a higher content of oxygen elements than the second inorganic layer 163. That is, the first inorganic layer 162 has a higher content of oxygen elements, thereby facilitating the formation of the encapsulation layer 160, and in particular the leveling of the organic liquid material from which the encapsulation layer 160 is formed. The second inorganic layer 163 has a lower content of oxygen elements or even does not contain an oxygen element, and thus has a better water-oxygen blocking effect, which improves the packaging effect of the display panel 100.

In some embodiments, in the multilayer stacked structure including the first inorganic layer 162, the organic layer 161, and the second inorganic layer 163, the deposition of the first inorganic layer 162 and the second inorganic layer 163 are performed by a Plasma Enhanced Chemical Vapor Deposition (PECVD) method or an Atomic Layer Deposition (ALD) method, so as to achieve efficient water and oxygen blocking requirements. The preparation of the organic layer 161 includes, but is not limited to, polymer monomer deposition, forming hybridized organic layers using PECVD, or Ink Jet Printing (IJP).

Referring to FIG. 12 or FIG. 13, the cover plate 120 is indirectly adhered to the display panel 100 through the transparent adhesive layer 110. In some embodiments, a back film 300 is further disposed between the transparent adhesive layer 110 and the cover plate 120. The cover plate 120 is indirectly adhered to the transparent adhesive layer 110 through the back film 300. In some embodiments, the cover plate 120 is a protective film. In some embodiments, the back film 300 is a transparent insulating material, such as polyester resin, and is configured to protect and support the display panel 100.

In some embodiments, the waterproof layer 170 is made of aluminum foil or copper foil. In the embodiments of the present disclosure, the waterproof layer 170, made of aluminum foil or copper foil, waterproofs the display panel 100 and the encapsulation layer 160. The waterproof layer made of aluminum foil or copper foil is more effective in waterproofing compared to waterproof layers made of other materials. In addition, the aluminum foil and the copper foil further play a role in electromagnetic shielding in the display module, which makes the display module have a better display performance during usage.

In some embodiments, referring to FIG. 12, in a direction parallel to a plane in which the substrate extends, an edge of the organic layer 161 is inwardly retracted by 1 mm to 2 mm relative to edges of the first inorganic layer 162 and the second inorganic layer 163. The display module further includes a first glue film 171. The first glue film 171 is disposed in the same layer as the organic layer 161. The first glue film 171 is configured to adhere the first inorganic layer 162 to the second inorganic layer 163. In other words, the first glue film 171 is disposed at the inward retraction position of the organic layer 161 to enable the first inorganic layer 162 and the second inorganic layer 163 to be adhered.

In the embodiments of the present disclosure, to prevent the liquid organic layer 161 from overflowing out of the first inorganic layer 162 and the second inorganic layer 163 and thus overflowing onto the display panel 100, during the formation of the organic layer 161, the organic layer 161 is inwardly retracted for a certain distance relative to the edge of the first inorganic layer 162, to prevent the liquid organic layer 161 from outflowing onto the display panel 100. The first glue film 171 is disposed at the inward retraction position of the organic layer 161, and the first glue film 171 plays a role in adhering the edges of the first inorganic layer 162 and the second inorganic layer 163, thereby reducing the probability of a gap formed at the corners of the display module. In addition, the first glue film 171 further fills the inward retraction vacancy of the organic layer 161, such that the first glue film 171 plays the role of sealing and preventing water vapor intrusion at the inward retraction position of the organic layer 161, thereby greatly reducing the defective rate of the display module, avoiding the exposure of the thin film encapsulation (TFE)) to a water vapor environment, and greatly lowering the erosion speed. Therefore, the vehicle trustworthiness specifications can be met, and the purpose of applying the flexible OLED screen to projects with special shapes, curved surfaces, or foldable forms, such as the vehicle window, center control, or lamps, is achieved.

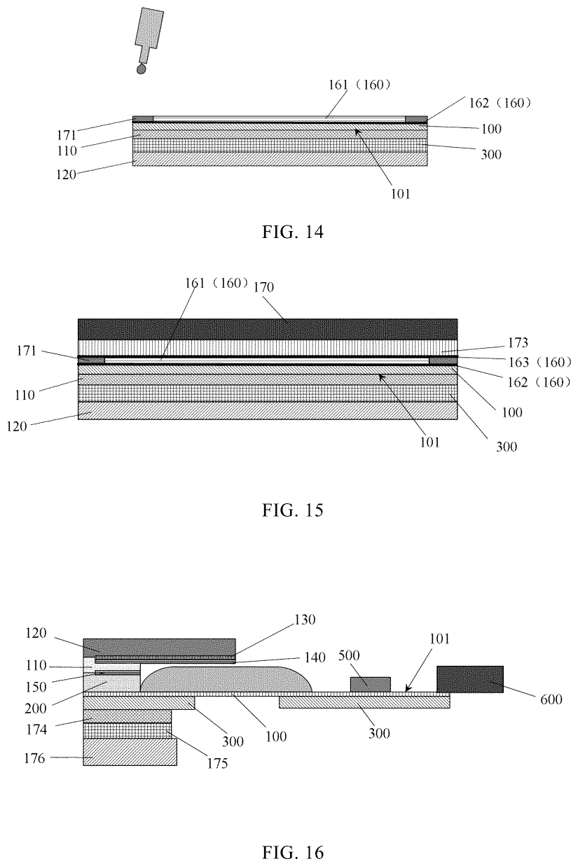

In some embodiments, the material of the first glue film 171 includes an optical clear resin, fluorinated glue, or the like. In some embodiments, the first glue film 171 is prepared by inkjet printing, coating, or the like. Referring to FIG. 12, in some embodiments, in the case that the display module is prepared, the first glue film 171 is coated on the inward retraction position of the organic layer 161, such that the first glue film 171, at the inward retraction position, adheres the first inorganic layer 162 to the second inorganic layer 163, thereby preventing the encapsulation layer 160 from intrusion of water vapor from the inward retraction position. Alternatively, as shown in FIG. 14, in the case that the organic layer 161 is formed, the first glue film 171 is first prepared at the inward retraction position of the organic layer 161. As shown in FIG. 15, in the case that the organic layer 161 and the first glue film 171 are prepared, the second inorganic layer 163, the first adhesive layer 173, and the waterproof layer 170 are then sequentially formed on the side, away from the display panel 100, of the organic layer 161 and the first glue film.

In some embodiments, referring to FIG. 13, in a direction parallel to a plane in which the substrate extends, the outer edges of the waterproof layer 170 and the second inorganic layer 163 are flush and both inwardly retracted by 0.5 mm to 1 mm relative to the edge of the first inorganic layer 162. The edge of the organic layer 161 is inwardly retracted by 1 mm to 2 mm relative to the edge of the first inorganic layer 162. The display module further includes a second glue film 172. The second glue film 172 covers a surface, away from the substrate, of the waterproof layer 170, and side surfaces of the waterproof layer 170, the first adhesive layer 173, the second inorganic layer 163, the organic layer 161, and the first inorganic layer 162.

In the embodiments of the present disclosure, the outer edge of the waterproof layer 170 is flush with the outer edge of the second inorganic layer 163, which enables the waterproof layer 170 to completely cover the second inorganic layer 163, and thus enables the waterproof layer 170 to exert a better waterproofing effect on the encapsulation layer 160. As shown in FIG. 13, the second glue film 172 covers the outer surface of the waterproof layer 170, such that another waterproof barrier is formed outside the waterproof layer 170, and water vapor cannot stick to the waterproof layer 170. For a waterproof layer made of metal, the second glue film 172 further insulates the waterproof layer from the air, which in turn prevents the waterproof layer 170 from rusting. The second glue film 172 further covers the side surfaces of the waterproof layer 170, the first adhesive layer 173, the first inorganic layer 162, the organic layer 161, and the second inorganic layer 163, so as to insulate the side surfaces of the waterproof layer 170, the first adhesive layer 173, the first inorganic layer 162, the organic layer 161, and the second inorganic layer 163 from the outside air, and to reduce the probability of water vapor entering the display module from the side surfaces of the waterproof layer 170, the first adhesive layer 173, the first inorganic layer 163, the organic layer 161, and the second inorganic layer 163. Therefore, the display module is further waterproofed, which in turn improves the working performance of the display module.

In some embodiments, in the case that the light-emitting device is a bottom-emitting device, because the light emitted by the light-emitting device does not pass through the first adhesive layer 173, the first adhesive layer 173 is a transparent adhesive layer or an opaque adhesive layer.

Illustratively, FIG. 16 is a cross-sectional view of an edge of the display module illustrated in FIG. 7 according to some embodiments of the present disclosure. As shown in FIG. 16, the display module further includes a second adhesive layer 174, a foam layer 175, a heat dissipation layer 176, and a polarizer 200. The second adhesive layer 174 is disposed on a side, away from the transparent adhesive layer 110, of the back film 300. In some embodiments, the second adhesive layer 174 is a pressure-sensitive adhesive. The foam layer 175 and the heat dissipation layer 176 are sequentially disposed on the second adhesive layer 174 at the side, away from the transparent adhesive layer 110, of the second adhesive layer 174. During the bending of the display panel 100, the foam layer 175 acts as a cushion. The foam layer 175 is adhered to the back film 300 through the second adhesive layer 174. The heat generated during the operation of the display panel 100 is dissipated through the heat dissipation layer 176, thereby avoiding the accumulation of heat within the display panel 100.

It should be noted that in a COE (Color filter on encapsulation) product, the polarizer 200 is replaced by PET in some embodiments. PET serves to increase the strength of the display product.

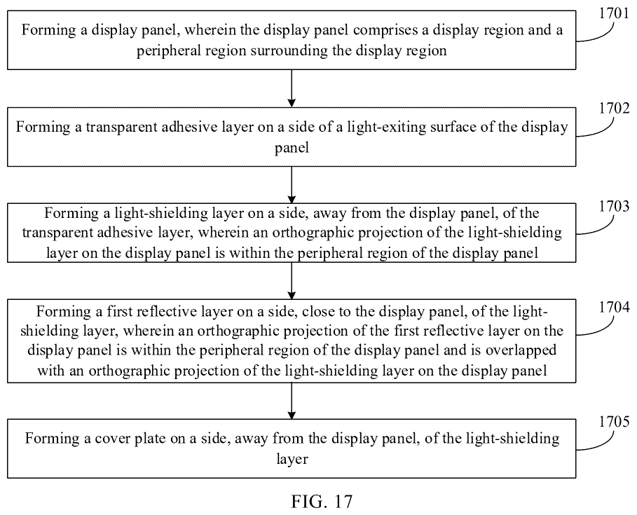

FIG. 17 is a flow chart of a method for manufacturing a display module according to some embodiments of the present disclosure. As shown in FIG. 17, the method includes, but is not limited to, the following processes 1701 to 1705.

In process 1701, a display panel is formed, wherein the display panel includes a display region and a peripheral region surrounding the display region.

In process 1702, a transparent adhesive layer is formed on a side of a light-exiting surface of the display panel.

In process 1703, a light-shielding layer is formed on a side, away from the display panel, of the transparent adhesive layer, wherein an orthographic projection of the light-shielding layer on the display panel is within the peripheral region of the display panel.

In process 1704, a first reflective layer is prepared on a side, close to the display panel, of the light-shielding layer, wherein an orthographic projection of the first reflective layer on the display panel is within the peripheral region of the display panel and overlapped with the orthographic projection of the light-shielding layer on the display panel.

In some embodiments, the process 1704 includes: forming the first reflective layer on the side, close to the display panel, of the light-shielding layer using a non-conductive vacuum metalization process, a coating process, a bonding or hot-melt process.

The non-conductive vacuum metalization process is also known as non-conductive plating technology. In the non-conductive vacuum metalization process, metal materials are converted into particles under vacuum conditions through organic transformation using specific chemical or physical means, and the particles are deposited or stuck onto a surface of a plastic material to form a film. The coating formed by the non-conductive vacuum metalization process has a metal texture in appearance and does not affect wireless communication.

In some embodiments of the present disclosure, the first reflective layer is formed by coating a reflective solution. Alternatively, the first reflective layer is prepared first, and then the first reflective layer is attached to the transparent adhesive layer.

In process 1705, a cover plate is formed on a side, away from the display panel, of the light-shielding layer.

The structure of the display module manufactured using the method according to the embodiments of the present disclosure as shown in FIG. 17 is the same as the structure shown in FIG. 1, FIG. 6, or FIG. 10. In the case that the curing light irradiates the transparent adhesive layer 110 along the side of the display module, even if the curing light is not parallel to the transparent adhesive layer 110, the curing light is reflected multiple times by the first reflective layer 140 to the transparent adhesive layer 110, rather than absorbed by the light-shielding layer 130. In this way, the efficient utilization of the curing light is achieved, and the transparent adhesive layer 110 is fully irradiated by the curing light, which in turn enables the edges of the transparent adhesive layer 110 to be fully cured, improves the folding trustworthiness of the display module, and improves the performance and competitiveness of the product.

In some embodiments, prior to forming the transparent adhesive layer on the side of the light-exiting surface of the display panel, a second reflective layer is formed on the side of the light-exiting surface of the display panel. An orthographic projection of the second reflective layer on the display panel is within the peripheral region of the display panel and overlapped with the orthographic projection of the light-shielding layer on the display panel. The structure of the display module manufactured by this method is the same as the structure shown in FIG. 4, FIG. 7 or FIG. 11.

In some embodiments, forming the second reflective layer on the side of the light-exiting surface of the display panel includes: forming the second reflective layer on the side of the light-exiting surface of the display panel using a non-conductive vacuum metalization process, a coating process, a bonding or hot-melt process.

In some embodiments, the first reflective layer and the second reflective layer are reflective layers made of a single material, or the first reflective layer and the second reflective layer have composite laminated structures, which are not limited in the embodiments of the present disclosure.

Embodiments of the present disclosure further provide a display device including any of the above-described display modules.

In the embodiments of the present disclosure, as shown in any one of FIG. 1, FIG. 4, FIGS. 6 to 7, and FIGS. 9 to 11, the display device including the above-described display module is provided with the first reflective layer 140 between the light-shielding layer 130 and the display panel 100. In the case that the curing light irradiates the transparent adhesive layer 110 along the side of the display device, even if the curing light is not parallel to the transparent adhesive layer 110, the curing light is reflected multiple times by the first reflective layer 140 to the transparent adhesive layer 110, rather than absorbed by the light-shielding layer 130. In this way, the efficient utilization of the curing light is achieved, and the transparent adhesive layer 110 is fully irradiated by the curing light, which in turn enables the edges of the transparent adhesive layer 110 to be fully cured, improves the folding trustworthiness of the display module, and improves the performance and competitiveness of the product.

In some embodiments, the display device includes, but is not limited to: a computer display, a television, a billboard, a laser printer with a display function, a telephone, a cellular phone, a personal digital assistant (PDA), a laptop computer, a digital camera, a portable camcorder, a viewfinder, a vehicle, a large-area wall, a screen in a theater, a stadium sign, or the like.

It should be noted that in the disclosure, relational terms such as first or second are used only to distinguish one entity or operation from another, but do not necessarily require or imply any actual relationship or order between those entities or operations. Furthermore, the terms “include,” “comprise”, or any other variant thereof, means non-exclusive inclusion, such that a process, method, object, or device comprising a set of elements includes not only those elements, but also other elements not expressly listed, or other elements being inherent in such process, method, object, or device. Without further limitation, the element defined by the phrase “including a . . . ” does not exclude the existence of other identical elements in the process, method, object, or device including the element.

The various embodiments in this description are described in a related manner, the same or similar features of the various embodiments can refer to other embodiments, and each embodiment focuses on the differences of the embodiment from other embodiments. In particular, because the system embodiments are basically similar to the method embodiments, the system embodiments are described in a simpler manner, and related contents can refer to the descriptions of the method embodiments.

The above descriptions are only some embodiments of the present disclosure and are not intended to limit the scope of protection of the present disclosure. Any modifications, equivalent substitutions, improvements, etc. made within the concept and principles of the present disclosure shall fall within the protection scope of the present disclosure.

1. A display module, comprising:
a display panel, wherein the display panel comprises a display region and a peripheral region surrounding the display region;
a transparent adhesive layer, wherein the transparent adhesive layer is disposed on a side of a light-exiting surface of the display panel;
a cover plate, wherein the cover plate is disposed on a side, away from the display panel, of the transparent adhesive layer;
a light-shielding layer, wherein the light-shielding layer is disposed between the cover plate and the display panel, and an orthographic projection of the light-shielding layer on the display panel is within the peripheral region of the display panel; and
at least one reflective layer, wherein the at least one reflective layer comprises a first reflective layer disposed between the transparent adhesive layer and the light-shielding layer, an orthographic projection of the first reflective layer on the display panel being within the peripheral region of the display panel and being overlapped with the orthographic projection of the light-shielding layer on the display panel.

2. The display module according to claim 1, wherein the orthographic projection of the first reflective layer on the display panel is completely overlapped with the orthographic projection of the light-shielding layer on the display panel.

3. The display module according to claim 1, wherein the at least one reflective layer further comprises a second reflective layer disposed between the transparent adhesive layer and the display panel, an orthographic projection of the second reflective layer on the display panel being within the peripheral region of the display panel and being overlapped with the orthographic projection of the light-shielding layer on the display panel.

4. The display module according to claim 3, wherein the orthographic projection of the second reflective layer on the display panel is completely overlapped with the orthographic projection of the light-shielding layer on the display panel.

5. The display module according to claim 1, wherein any of the at least one reflective layer comprises a plurality of layers of composite structure, each of the plurality of layers of composite structure comprising niobium oxide and silicon dioxide arranged in a stacked configuration.

6. The display module according to claim 5, wherein any of the at least one reflective layer comprises five layers of composite structure, each of the five layers of composite structure having a thickness ranging from 100 nm to 800 nm.

7. The display module according to claim 1, wherein the light-shielding layer comprises a first flat portion and a second flat portion sequentially stacked in a direction close to the light-exiting surface of the display panel, an area of an orthographic projection of the first flat portion on the display panel being greater than an area of an orthographic projection of the second flat portion on the display panel.

8. The display module according to claim 7, wherein the orthographic projection of the second flat portion on the display panel is within a center region of the orthographic projection of the first flat portion on the display panel.

9. The display module according to claim 1, wherein a cross-section of the light-shielding layer in a direction perpendicular to the light-exiting surface of the display panel is at least one of: a planar shape, a wavy shape, or a groove structure, the groove structure having an opening facing the display panel.

10. The display module according to claim 1, wherein a material of the transparent adhesive layer comprises an optically clear adhesive or an optical clear resin.

11. The display module according to claim 1, wherein the display panel comprises a substrate and a plurality of light-emitting devices, a pixel definition layer, and a encapsulation layer sequentially disposed on a side of the substrate, the pixel definition layer being configured to separate the plurality of light-emitting devices.

12. The display module according to claim 11, wherein
the light-emitting device is a bottom-emitting device, and the encapsulation layer comprises a first inorganic layer, an organic layer, and a second inorganic layer that are stacked in a direction away from the substrate; and
the display module further comprises a waterproof layer and a first adhesive layer, the waterproof layer being disposed on a side, away from the substrate, of the second inorganic layer, and the first adhesive layer being disposed between the second inorganic layer and the waterproof layer.

13. The display module according to claim 12, wherein the waterproof layer is made of aluminum foil or copper foil.

14. The display module according to claim 12, wherein
in a direction parallel to a plane in which the substrate extends, an edge of the organic layer is inwardly retracted by 1 mm to 2 mm relative to edges of the first inorganic layer and the second inorganic layer; and
the display module further comprises a first glue film, the first glue film being disposed in the same layer as the organic layer and configured to adhere the first inorganic layer to the second inorganic layer.

15. The display module according to claim 12, wherein
in a direction parallel to a plane in which the substrate extends, outer edges of the waterproof layer and the second inorganic layer are flush and both inwardly retracted by 0.5 mm to 1 mm relative to an edge of the first inorganic layer, and an edge of the organic layer is inwardly retracted by 1 mm to 2 mm relative to the edge of the first inorganic layer; and
the display module further comprises a second glue film, the second glue film covering a surface, away from the substrate, of the waterproof layer, and side surfaces of the waterproof layer, the first adhesive layer, the second inorganic layer, the organic layer, and the first inorganic layer.

16. A method for manufacturing a display module, applicable to manufacturing the display module as defined in claim 1, the method comprising:
forming a display panel, wherein the display panel comprises a display region and a peripheral region surrounding the display region;
forming a transparent adhesive layer on a side of a light-exiting surface of the display panel;
forming a light-shielding layer on a side, away from the display panel, of the transparent adhesive layer, wherein an orthographic projection of the light-shielding layer on the display panel is within the peripheral region of the display panel;
forming a first reflective layer on a side, close to the display panel, of the light-shielding layer, wherein an orthographic projection of the first reflective layer on the display panel is within the peripheral region of the display panel and is overlapped with an orthographic projection of the light-shielding layer on the display panel; and
forming a cover plate on a side, away from the display panel, of the light-shielding layer.

17. The method according to claim 16, wherein forming the first reflective layer on the side, close to the display panel, of the light-shielding layer comprises:
forming the first reflective layer on the side, close to the display panel, of the light-shielding layer through a non-conductive vacuum metalization process, a coating process, a bonding or hot-melt process.

18. The method according to claim 16, wherein prior to forming the transparent adhesive layer on the side of the light-exiting surface of the display panel, the method further comprises:
forming a second reflective layer on the side of the light-exiting surface of the display panel, wherein an orthographic projection of the second reflective layer on the display panel is within the peripheral region of the display panel and is overlapped with the orthographic projection of the light-shielding layer on the display panel.

19. The method according to claim 18, wherein forming the second reflective layer on the side of the light-exiting surface of the display panel comprises:
forming the second reflective layer on the side of the light-exiting surface of the display panel through a non-conductive vacuum metalization process, a coating process, a bonding or hot-melt process.

20. A display device, comprising a display module, wherein the display module comprises:
a display panel, wherein the display panel comprises a display region and a peripheral region surrounding the display region;
a transparent adhesive layer, wherein the transparent adhesive layer is disposed on a side of a light-exiting surface of the display panel;
a cover plate, wherein the cover plate is disposed on a side, away from the display panel, of the transparent adhesive layer;
a light-shielding layer, wherein the light-shielding layer is disposed between the cover plate and the display panel, and an orthographic projection of the light-shielding layer on the display panel is within the peripheral region of the display panel; and
at least one reflective layer, wherein the at least one reflective layer comprises a first reflective layer disposed between the transparent adhesive layer and the light-shielding layer, an orthographic projection of the first reflective layer on the display panel being within the peripheral region of the display panel and being overlapped with the orthographic projection of the light-shielding layer on the display panel.
